(19) United States
(12) Patent Application Publication
(10) Pub. No.: US 2026/0351530 A1
(43) Pub. Date: Nov. 5, 2026

(54) ACTIVE COOLING IN HEATER ELECTROSTATIC CHUCK

(71) Applicant: Applied Materials, Inc., Santa Clara, CA (US)

(72) Inventors: Abhilash Simha Kalenahalli Vedavyasachar, Bangalore (IN); Arvinder ManmohanSingh Chadha, San Jose, CA (US)

(21) Appl. No.: 19/660,613

(22) Filed: Apr. 28, 2026

Related U.S. Application Data
(60) Provisional application No. 63/800,334, filed on May 5, 2025.

(51) Int. Cl. H01J 37/32

(52) U.S. Cl. CPC H01J 37/32724; H01J 2237/2007

(57) ABSTRACT

A substrate support assembly includes an electrostatic chuck configured to support a substrate. The substrate support assembly further includes one or more heater shafts disposed below the electrostatic chuck. The one or more heater shafts form one or more gas pathways and are configured to provide gas through the electrostatic chuck. The substrate support assembly further includes a heater shaft assembly disposed below the one or more heater shafts. The substrate support assembly further includes a heater ring clamp configured to secure at least one of the one or more heater shafts to the heater shaft assembly.

### RELATED APPLICATIONS

This application claims the benefit of U.S. Provisional Patent Application No. 63/800,334 filed May 5, 2025, the contents of which are incorporated by reference in their entirety herein.

### TECHNICAL FIELD

Embodiments of the present disclosure relate to electrostatic chucks, such as those used in association with substrate processing systems, and in particular to active cooling in heater electrostatic chucks.

### BACKGROUND

In substrate processing and other electronics processing, processing chambers are used to perform substrate processing operations. Temperatures of substrates in the processing chambers are to be controlled to avoid defects.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a substrate support assembly includes an electrostatic chuck configured to support a substrate. The substrate support assembly further includes one or more heater shafts disposed below the electrostatic chuck. The one or more heater shafts form one or more gas pathways and are configured to provide gas through the electrostatic chuck. The substrate support assembly further includes a heater shaft assembly disposed below the one or more heater shafts. The substrate support assembly further includes a heater ring clamp configured to secure at least one of the one or more heater shafts to the heater shaft assembly.

In another aspect of the disclosure, a substrate support assembly includes an electrostatic chuck configured to support a substrate. The substrate support assembly further includes an inner heater shaft disposed below the electrostatic chuck. The substrate support assembly further includes an outer heater shaft disposed around the inner heater shaft below the electrostatic chuck. One or more gas pathways are formed between the inner heater shaft and the outer heater shaft that provide gas through the electrostatic chuck to provide at least one of cooling or vacuum clamping. The substrate support assembly further includes a heater shaft assembly disposed below the inner heater shaft and the outer heater shaft.

In another aspect of the disclosure, a substrate support assembly includes an electrostatic chuck configured to support a substrate. The substrate support assembly further includes a heater shaft disposed below the electrostatic chuck. The heater shaft forms one or more though holes that are configured to provide gas through the electrostatic chuck to provide at least one of cooling or vacuum clamping. The substrate support assembly further includes a heater shaft assembly disposed below the heater shaft.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 illustrates a substrate support assembly, according to certain embodiments.

FIGS. 2A-D illustrate components of substrate support assemblies, according to certain embodiments.

FIGS. 3A-E illustrate components of substrate support assemblies, according to certain embodiments.

FIGS. 4A-B illustrate components of substrate support assemblies, according to certain embodiments.

FIGS. 5A-H illustrate components of substrate support assemblies, according to certain embodiments.

FIGS. 6A-B illustrate components of substrate support assemblies, according to certain embodiments.

### DETAILED DESCRIPTION OF EMBODIMENTS

Embodiments described herein are related to at least one of active cooling or vacuum clamping associated with an electrostatic chuck (e.g., active cooling in heater electrostatic chuck with gas flow, actively cooled heater electrostatic chuck, vacuum clamping of a substrate).

In substrate processing, a substrate may be placed on an electrostatic chuck and a deposition process takes place on the substrate. The substrate and components of the substrate processing equipment (e.g., electrostatic chuck, shaft below the electrostatic chuck, etc.) are heated by the deposition process.

The substrate and the components of the substrate processing equipment are to be cooled which conventionally takes an extended amount of time. This decreases the yield of the substrate processing system. If adequate cooling is not accomplished, this may damage the substrates and/or the components of the substrate processing system. The substrate is to be clamped to the chuck. If the substrate is not adequately clamped, this may damage the substrates and/or components of the substrate processing system.

Conventionally, the substrate is not uniformly cooled and/or is not uniformly chucked. This causes non-uniform substrates, damaged substrates, and decreased yield.

Conventionally, during the deposition process on an upper surface of the substrate, deposition may partially occur on a lower surface of the substrate. This may cause defects in the substrate and damage to components of the substrate processing system.

The systems, devices, and methods of the present disclosure provide solutions to these and other problems of conventional systems.

In some embodiments, a substrate support assembly of the present disclosure includes an electrostatic chuck configured to support a substrate. The electrostatic chuck forms forming chuck gas channels from a lower surface of the electrostatic chuck to an upper surface of the electrostatic chuck.

The substrate support assembly further includes one or more heater shafts disposed below the electrostatic chuck (e.g., at least one of the one or more heater shafts is bonded to the lower surface of the electrostatic chuck). The one or more heater shafts form one or more gas pathways and are configured to provide gas through the electrostatic chuck to at least one of provide cooling to manage thermal uniformity of the substrate in a deposition environment (e.g., one or more shaft gas channels configured to provide gas to the chuck gas channels) or provide vacuum clamping on the substrate to enable thermal tuning of the substrate in the deposition environment. In some embodiments, the one or more shafts include an outer shaft and an inner shaft (e.g., concentric shafts, annulus-type shafts) and the one or more shaft gas channels is the spacing between the outer shaft and the inner shaft (e.g., using O-rings). In some embodiments, the one or more shafts include a single shaft (e.g., monolithic shaft) that forms the one or more shaft gas channels. In some embodiments, the gas is an inert gas (e.g., helium, argon, nitrogen, etc.).

The substrate support assembly further includes a heater shaft assembly disposed below the one or more heater shafts. The substrate support assembly further includes a heater ring clamp configured to secure at least one of the one or more heater shafts to the heater shaft assembly.

In some embodiments, one or more chuck gas channels provide the gas to a lower surface of the substrate to substantially uniformly cool the substrate. In some embodiments, one or more chuck gas channels provide the gas from the chamber to the heater shafts to substantially uniformly chuck the substrate. In some embodiments, one or more chuck gas channels provide the gas to and/or from the perimeter of the substrate to decrease (e.g., prevent) deposition of the lower surface of the substrate.

In some embodiments, one or more process kit rings are provided around the electrostatic chuck. In some embodiments, the one or more process kit rings form gas channels that provide gas to and/or from the perimeter of the substrate to decrease (e.g., prevent) deposition of the lower surface of the substrate. In some embodiments, the gas channels of the one or more process kit rings receive the gas from the shaft gas channels.

In some embodiments, the substrate support assembly (e.g., high temperature susceptor) is configured to be used in substrate processing operations of at least 100 degrees Celsius, at least 200 degrees Celsius, at least 300 degrees Celsius, at least 400 degrees Celsius, at least 500 degrees Celsius, or at least 600 degrees Celsius. The substrate support assembly may be configured to cool and/or vacuum chuck the substrate during or after substrate processing operations (e.g., plasma operations) that are at least 400 degrees Celsius.

The systems, devices, and methods of the present disclosure have advantages over conventional solutions. The present disclosure may provide a more uniform and/or quicker cooling and/or vacuum chucking of substrates and/or components of the substrate processing system than conventional solutions. The present disclosure may decrease (e.g., prevent) processing of the lower surface of substrates. The present disclosure may increase substrate yield, increase substrate quality, and/or decrease damage to the substrate processing system compared to conventional solutions.

The illustrated figures of substrate support assemblies of the present disclosure are shown below (not all illustrated features may be used, some features may be omitted or changed, additional features may be added, dimensions may be changed, components may be combined, components may be separated).

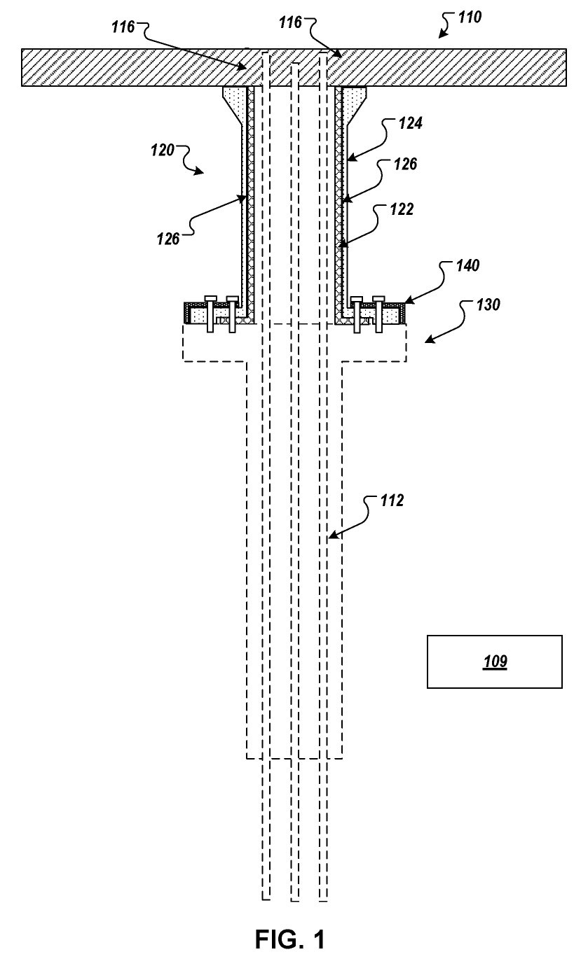

FIG. 1 illustrates a substrate support assembly 100, according to certain embodiments. In some embodiments, the substrate support assembly 100 includes one or more of an electrostatic chuck (ESC) 110, one or more heater shafts 120 disposed below the ESC 110, a heater shaft assembly 130, and a heater ring clamp 140 that connects the heater shaft assembly 130 and at least one of the one or more heater shafts 120.

In some embodiments, the ESC 110 supports a substrate. In some embodiments, the ESC 110 has electrodes to electrostatically chuck the substrate. In some embodiments, the ESC 110 forms gas pathways 126 from a lower surface to an upper surface of the ESC 110. In some embodiments, an upper surface of the ESC 110 has protrusions (e.g., mesas) to support the substrate. In some embodiments, ESC 110 has different zones to provide different heat transfer for different portions of a substrate. In some embodiments, an upper surface of the ESC 110 forms one or more pockets (e.g., recesses) to receive one or more substrates (e.g., one substrate per pocket).

In some embodiments, the ESC 110 is one or more of a susceptor body, a vacuum chuck, a susceptor, a workpiece support surface, and/or the like. In some embodiments, the ESC 110 chucks (e.g., secures) the substrate to an upper surface of the ESC 110 (e.g., to make secure contact, to make uniform contact, etc. with the ESC 110). A substrate may refer to a wafer, semiconductor, glass, glass substrate, electronic device, glass device, display device, and/or the like.

The one or more heater shafts 120 form one or more gas pathways 126 and are configured to provide gas through the ESC 110 to provide cooling and/or vacuum chucking to manage thermal uniformity of the substrate in a deposition environment (e.g., in a processing chamber).

In some embodiments, the one or more heater shafts 120 have a different thermal conductivity (e.g., lower thermal conductivity) than the ESC 110. The ESC 110 may be diffusion bonded (e.g., non-removably connected, bonded, etc.) to at least one of the one or more heater shafts 120.

In some embodiments, the one or more heater shafts 120 include an inner heater shaft 122 and outer heater shaft 124 disposed around the inner heater shaft 122. The one or more gas pathways 126 may be between the inner heater shaft 122 and the outer heater shaft 124. The inner heater shaft 122 and the outer heater shaft 124 may be non-removably connected (e.g., brazed, diffusion bonded, etc.) together.

In some embodiments, the one or more heater shafts 120 include a single heater shaft, where the one or more gas pathways 126 are one or more through holes that pass through the single heater shaft.

The one or more gas pathways 126 formed by the one or more heater shafts 120 may provide gas to one or more gas channels 116 formed by the ESC 110 to a location below a substrate disposed on the ESC 110.

The heater shaft assembly 130 is disposed below the one or more heater shafts 120. In some embodiments, the substrate support assembly 100 includes one or more sealing components (e.g., gaskets, O-rings, etc.) disposed between at least one of the one or more heater shafts 120 and the heater shaft assembly 130. Gas may be provided from the heater shaft assembly 130 to the one or more gas pathways 126 formed by the one or more heater shafts 120.

The heater ring clamp 140 is configured to secure (e.g., connect) at least one of the one or more heater shafts 120 to the heater shaft assembly 130.

In some embodiments, the gas comprises one or more of nitrogen, argon, or helium. In some embodiments, one or more electrical conduits 112 pass through a central portion of the one or more heater shafts 120 to the ESC 110. The one or more heater shafts 120 may be hollow (e.g., form a channel through the central portion of the one or more heater shafts 120) so that components (e.g., electrical conduits 112, etc.) can pass from the heater shaft assembly 130 through the one or more heater shafts 120 to the ESC 110. In some embodiments, the gas is to provide cooling and/or vacuum chucking of a substrate that is disposed on the ESC 110 and that is processed with processing temperatures of at least 100 degrees Celsius, at least 200 degrees Celsius, at least 300 degrees Celsius, at least 400 degrees Celsius, at least 500 degrees Celsius, or at least 600 degrees Celsius.

In some embodiments, the substrate support assembly 100 is disposed in a processing chamber, such as a plasma treatment chamber, an annealing chamber, physical vapor deposition (PVD) chamber, chemical vapor deposition (CVD) chamber, ion implantation chamber, etch chamber, deposition chamber (e.g., atomic layer deposition (ALD) chamber, chemical vapor deposition (CVD) chamber, physical vapor deposition (PVD) chamber, and/or plasma enhanced (PE) versions thereof, such as PEALD, PECVD, PEPVD, etc.), anneal chamber, or the like. In some embodiments, the processing chamber has a high density plasma (HDP) source that has a high temperature (e.g., at least 100 degrees Celsius, above 100 degrees Celsius, at least 200 degrees Celsius, above 200 degrees Celsius, at least 300 degrees Celsius, at least 400 degrees Celsius, at least 500 degrees Celsius, or at least 600 degrees Celsius) to provide a massive heat to the substrate. Conventionally, the substrate cooling occurs very slowly and non-uniformly which increases the amount of time to finish processing a substrate and increases substrate defects. This decreases yield.

In some embodiments, the ESC 110 (e.g., susceptor body) includes ceramic material. In some embodiments, the ESC 110 includes a metal matrix and/or a ceramic material. The metal matrix can be one or more of an aluminum matrix, magnesium matrix, titanium matrix, cobalt matrix, cobalt-nickel alloy matrix. The ceramic can be one or more of silicon carbide, carbon fiber, boron filament, alumina, etc. The ceramic may be a particle, fiber, filament, and/or the like. In some embodiments, the ESC 110 is about 70% volume ceramic and about 30% volume metal. In some embodiments, the ESC 110 is at least about 40% volume ceramic (e.g., at least about 50% volume ceramic particles). In some embodiments, the ESC 110 is made by dispersing a reinforcing material (e.g., ceramic particles) into a metal matrix. In some embodiments, the reinforcing material is coated (e.g., carbon fibers coated with nickel or titanium boride) to prevent a chemical reaction with the metal matrix. The metal matrix may be a monolithic material into which the reinforcing material is embedded.

In some embodiments, the ESC 110 includes a coating (e.g., plasma-spray coating, e-chuck layer, alumina, one or more dielectric materials, etc.). The coating may be an upper surface of the ESC 110. The coating may protect the ESC 110 from substrate processing operations. In some embodiments, a corresponding coefficient of thermal expansion (CTE) of the ESC 110 and the coating are within a threshold range (e.g., about 10%, about 5%, or about 1%) of one another.

In some embodiments, the one or more heater shafts 120 is diffusion bonded to a bottom surface of the ESC 110. The one or more heater shafts 120 form one or more gas pathways 126. Gas (e.g., helium, argon, nitrogen, etc.) flows through the gas pathways 126. Gas channels 116 (e.g., holes, openings, channels) formed by the ESC 110 (e.g., holes in the coating, channels from a lower surface to an upper surface, etc.) align with one or more of the gas pathways 126 formed by the one or more heater shafts 120. The gas flows through the gas pathways 126 formed by the one or more heater shafts and the gas channels 116 formed by the ESC 110 to a location above the ESC 110 (e.g., a location below the substrate). In some embodiments, the one or more heater shafts 120 distributes the gas substantially evenly through the gas channels 116 formed by the ESC 110 to different locations under the substrate. The ESC 110 may use a voltage (e.g., provided by electrical conduits 112) to secure the substrate to the ESC 110. The pressure provided by the gas flowing through the gas pathways 126 formed by the one or more heater shafts 120 and gas channels 116 formed by the ESC 110 may be less than the pressure provided by the voltage of the ESC 110 that is securing the substrate to the ESC 110. In some embodiments, at least a portion of the one or more heater shafts 120 includes a coating (e.g., plasma spray coating, alumina, dielectric materials, etc.) to prevent corrosion during substrate processing.

The processing chamber may be used to perform substrate processing operations that increase temperature within the processing chamber. The substrate support assembly 100 may cool and/or vacuum chuck the susceptor via the flowing of gas during and/or after the performing of the substrate processing operations.

In some embodiments, a controller 109 controls various aspects of the substrate support assembly 100, processing chamber, robot, one or more control valves, and/or substrate processing system. The controller 109 is and/or includes a computing device such as a personal computer, a server computer, a programmable logic controller (PLC), a microcontroller, and so on. The controller 109 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 109 includes a data storage device (e.g., one or more disk drives and/or solid state drives), a main memory, a static memory, a network interface, and/or other components. In some embodiments, the controller 109 executes instructions to perform any one or more of the methods or processes described herein. The instructions are stored on a computer readable storage medium, which include one or more of the main memory, static memory, secondary storage and/or processing device (during execution of the instructions). In some embodiments, controller 109 is used to control one or more parameters (e.g., temperature, pressure, flow rate, voltage, etc.) of the substrate support assembly 100. The controller 109 receives sensor data from one or more sensors associated with the substrate support assembly 100.

In some embodiments, one or more sensors provide sensor data to the controller 109. A sensor may include one or more of a thermocouple sensor, heat sensor, temperature sensor, pressure sensor, flow rate sensor, voltage sensor, and/or the like. A sensor may be disposed proximate the substrate disposed on the ESC 110 (e.g., in the ESC 110, on an upper surface of the ESC 110, proximate an upper surface of the ESC 110, etc.).

In some embodiments, the controller 109 receives, from a sensor (e.g., thermocouple, heat sensor, temperature sensor), sensor data associated with a temperature of the substrate (e.g., temperature of the ESC 110). Responsive to the temperature of the substrate meeting a first threshold temperature (e.g., being greater than about 400 degrees Celsius), the controller 109 causes gas to flow via the one or more heater shafts 120 and ESC 110 to a location below the substrate to cool the substrate and/or from a location below the substrate to vacuum chuck the substrate.

Responsive to a substrate 160 being placed on the substrate support assembly 100, the substrate processing equipment being actuated (e.g., turned on, actuated by the controller 109), and/or responsive to controller 109 receiving sensor data (e.g., temperature data) indicating the processing chamber meets a threshold temperature (e.g., is at an active state, is above 400 degrees Celsius), controller 109 may cause a flowrate adjustment device (e.g., valve, pump, recirculation pump, etc.) to cause gas (e.g., helium, argon, nitrogen, inert gas, etc.) to flow via the one or more heater shafts 120 and ESC 110 to an upper surface of the substrate support assembly 100 (e.g., under the substrate) to cool the substrate. Controller 109 may cause gas to flow from an upper surface of the substrate support assembly 100 to vacuum chuck the substrate.

In some embodiments, the one or more heater shafts 120 (e.g., inner heater shaft 122 and/or outer heater shaft 124) are made of a ceramic (e.g., aluminum nitride (AlN)).

In some embodiments, the ESC 110 includes one or more of a heater, radio frequency (RF) electrodes, and/or clamp electrodes. The RF electrodes may extend beyond the clamp electrode. The heater may have a shaft that may have fluid flow. In some embodiments, the inner heater shaft 122 and the outer heater shaft 124 are brazen tougher so that fluid (e.g., gas) flows between the inner heater shaft 122 and the outer heater shaft 124. In some embodiments, there one heater shaft 120 has through holes to flow the gas to the ESC 110. One or more of the heater shafts 120 may be brazen or diffusion bonded to the ESC 110.

Gas may flow along the shaft (e.g., one or more heater shafts 120) to the back side of the substrate (e.g., wafer).

The substrate support assembly 100 may not have a separately attached cooling hub. The one or more heater shafts 120 that form gas pathways 126 may provide better heat transfer (e.g., better thermal uniformity of the substrate in a deposition environment, to the ESC 110, to the one or more heater shafts 120, etc.) than a separately attached cooling hub.

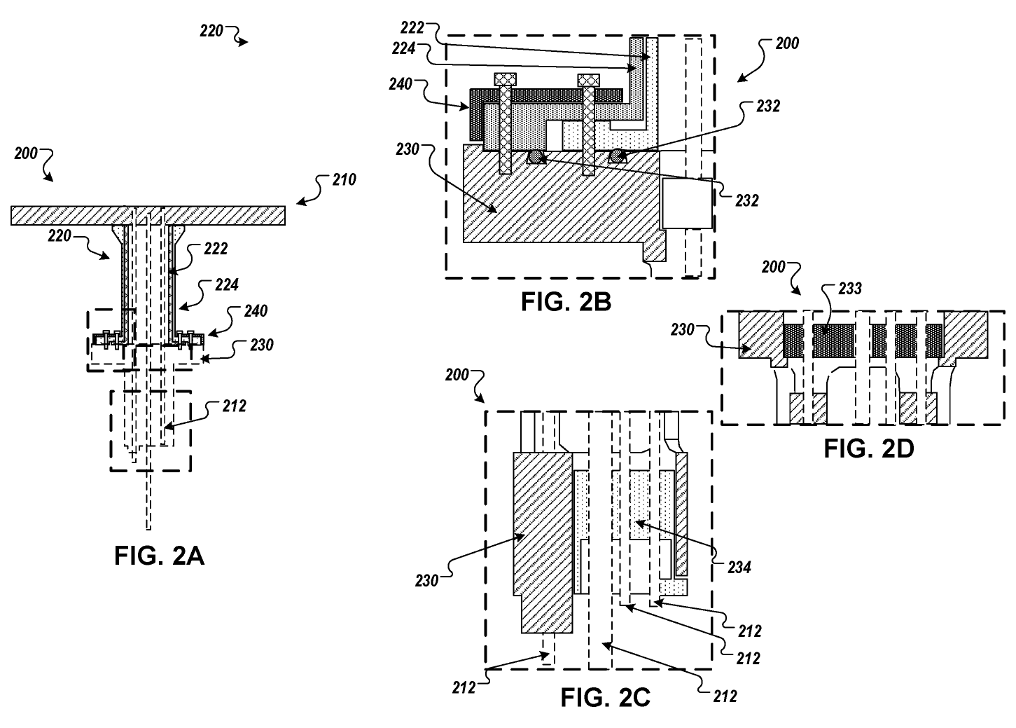

FIGS. 2A-D illustrates components of substrate support assemblies 200 (e.g., substrate support assembly 100 of FIG. 1), according to certain embodiments. FIG. 2A illustrates an overall cross-sectional view of a substrate support assembly 200. FIGS. 2B-D illustrate enlarged cross-sectional views of a components of a substrate support assembly 200.

FIG. 2B illustrates the heater ring clamp 240 and surrounding supports. In some embodiments, one or more sealing components 232 are disposed (e.g., in a groove formed by heater shaft assembly 230) between heater shaft assembly 230 and the one or more heater shafts 220. In some embodiments, a first sealing component 232 is disposed (e.g., in a groove formed by heater shaft assembly 230) between heater shaft assembly 230 and inner heater shaft 222 and a second sealing component 232 is disposed (e.g., in a groove formed by heater shaft assembly 230) between heater shaft assembly 230 and outer heater shaft 224.

FIG. 2C illustrates a portion of heater shaft assembly 230. One or more electrical conduits 212 may be partially disposed in heater shaft assembly 230. An electrical conduit support housing 234 (e.g., RF rod support housing) may be disposed in the heater shaft assembly 230 and may support one or more electrical conduits 212. An outer portion of the heater shaft assembly 230 (e.g., heater shaft body) may secure one or more electrical conduits 212.

FIGS. 2D illustrates a portion of the heater shaft assembly 230. An insulator guide 233 (e.g., bottom insulator guide) may be disposed in the heater shaft assembly 230 and may support (e.g., and insulate) one or more electrical conduits 212.

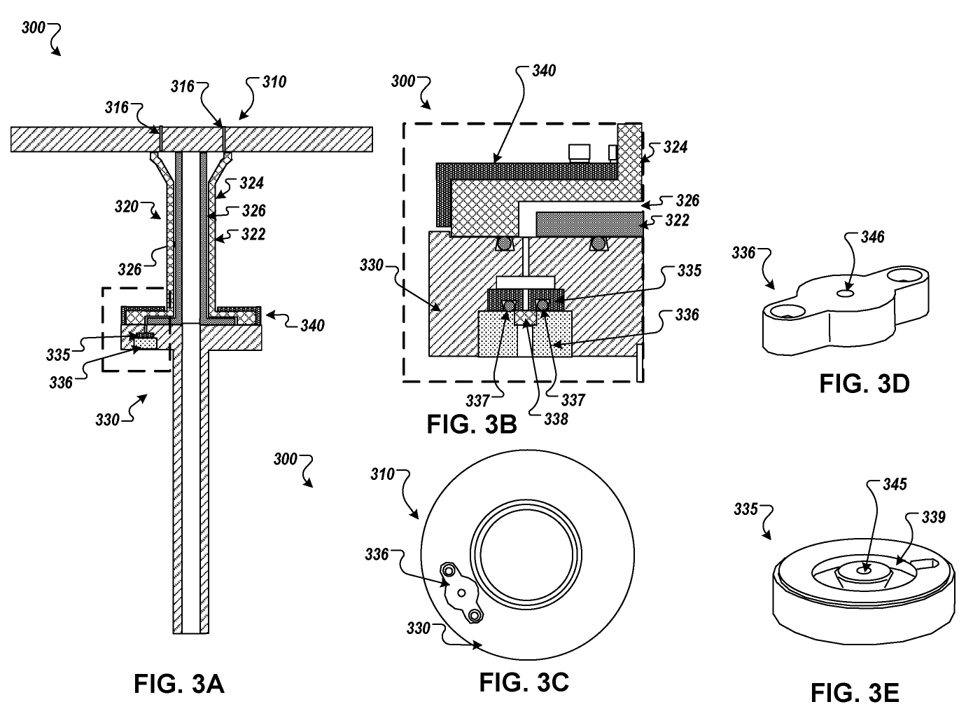

FIGS. 3A-E illustrates components of substrate support assemblies 300 (e.g., substrate support assemblies 200 of one or more of FIGS. 2A-D and/or substrate support assembly 100 of FIG. 1), according to certain embodiments. FIG. 3A illustrates an overall cross-sectional view of a substrate support assembly 300. FIG. 3B illustrates an enlarged view of components of a substrate support assembly 300. FIG. 3C illustrates a lower view of components of a substrate support assembly 300. FIGS. 3D-E illustrate perspective views of components of a substrate support assembly 300.

In some embodiments, gas (e.g., helium, argon, nitride, inert gas) is provided in the heater shaft assembly 130 through a gas introducer 336 (e.g., helium introducer). Sealing may be provided by one or more sealing components 337 (e.g., one or more gaskets, one or more O-rings).

The gas may flow through the gas channel cover 335 (e.g., helium channel cover) and move towards the gap (e.g., gas pathway 326) between the inner heater shaft 322 and the outer heater shaft 324 and come out through the ESC 110 (e.g., puck, through one or more gas channels 316). The ESC 110 (e.g., puck) can have a seal band in which case the backside gas leaks based on one or more of: the surface roughness and flatness of the seal; and/or flatness and morphology of the wafer. The ESC 110 may not have a seal band and may prevent backside deposition.

Referring to FIG. 3B, the substrate support assembly 300 includes a gas channel cover 335 forming a gas channel cover channel 345 and a gas introducer 336 forming a gas introducer channel 346. The gas is to be provided through the gas introducer channel 345 and the gas channel cover channel 346 to the one or more gas pathways 326. In some embodiments, the substrate support assembly 300 includes one or more sealing components 337 disposed (e.g., disposed in one or more recesses 339 formed by gas channel cover 335) between the gas channel cover 335 and the gas introducer 336.

In some embodiments, the substrate support assembly 300 includes a porous plug 338 (e.g., to prevent plasma arching, increase physical distance that the gas will travel to increase the minimum voltage that would allow plasma arching) at least partially disposed in at least one of the gas introducer channel 346, the gas channel cover channel 345 (e.g., in a counter bore of the gas introducer channel 346), or the electrostatic chuck.

FIG. 3C illustrates a lower view of the gas introducer 336 disposed in the heater shaft assembly 330.

FIG. 3D illustrates a perspective view of the gas introducer 336 (e.g., gas introducer structure) that forms a gas introducer channel 346 (e.g., through a central portion of the gas introducer 336).

FIG. 3E illustrates a perspective view of the gas channel cover 335 (e.g., gas channel cover structure) that forms a gas channel cover channel 345. An end face of the gas channel cover 335 may form one or more recesses 339 (e.g., annular groove, etc.) configured to receive one or more sealing components 337 (e.g., an annular gasket).

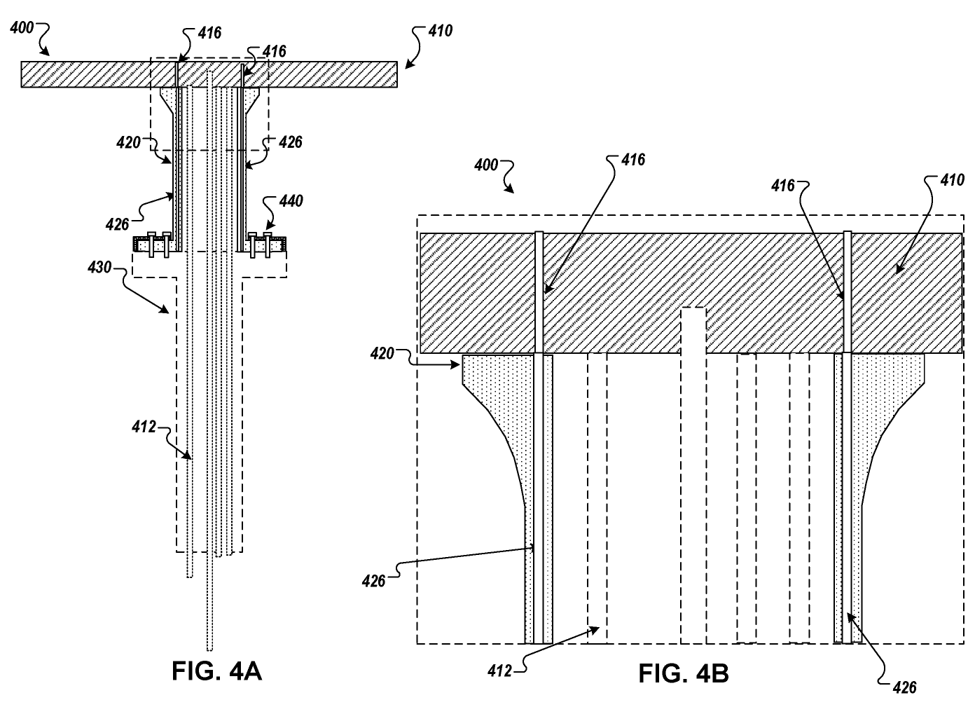

FIGS. 4A-B illustrates components of substrate support assemblies 400 (e.g., substrate support assemblies 300 of one or more of FIGS. 3A-E, substrate support assemblies 200 of one or more of FIGS. 2A-D, and/or substrate support assembly 100 of FIG. 1), according to certain embodiments.

In some embodiments, the substrate support assembly 400 includes a single heater shaft 420 that forms one or more gas pathways 426. Heater shaft assembly 430 may provide gas to the gas pathway 426 formed by the heater shaft 420 that provides the gas through gas channel 416 formed by the ESC 410 to the underside of a substrate.

The heater shaft 420 may have a threshold thickness (e.g., thick shaft) to form the gas pathway 426. The gas (e.g., helium, argon, nitrogen, inert gas, etc.) may flow through the heater shaft 420 to the ESC 410 (e.g., ceramic structure).

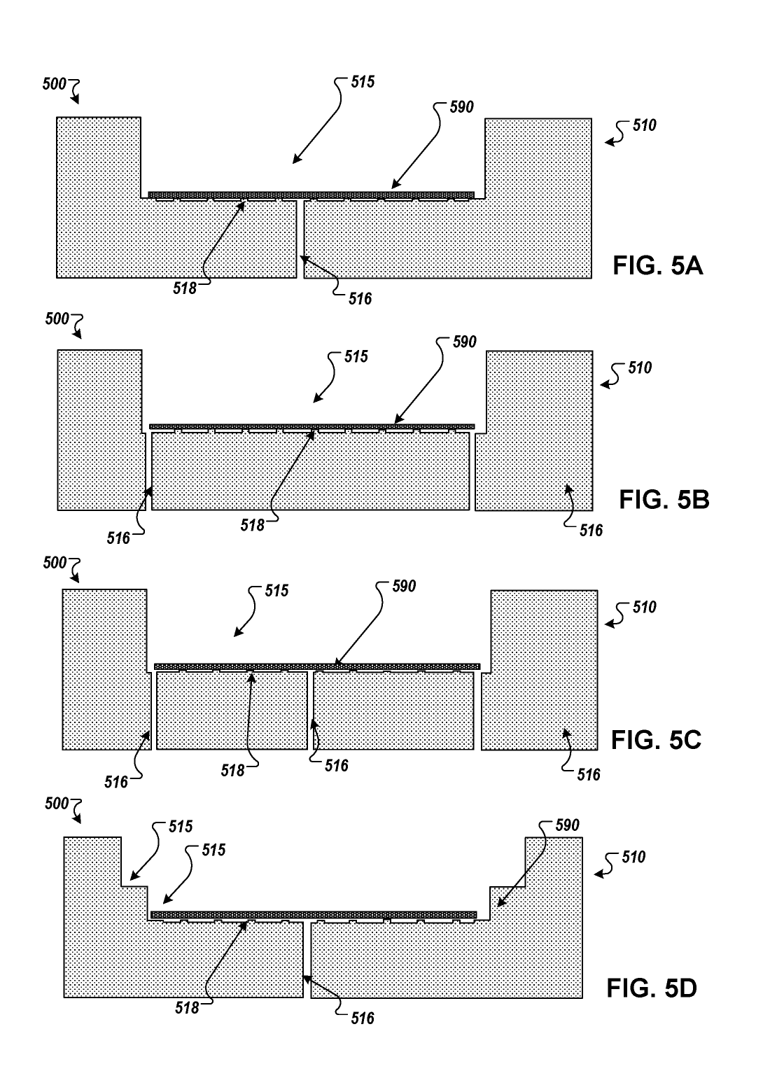

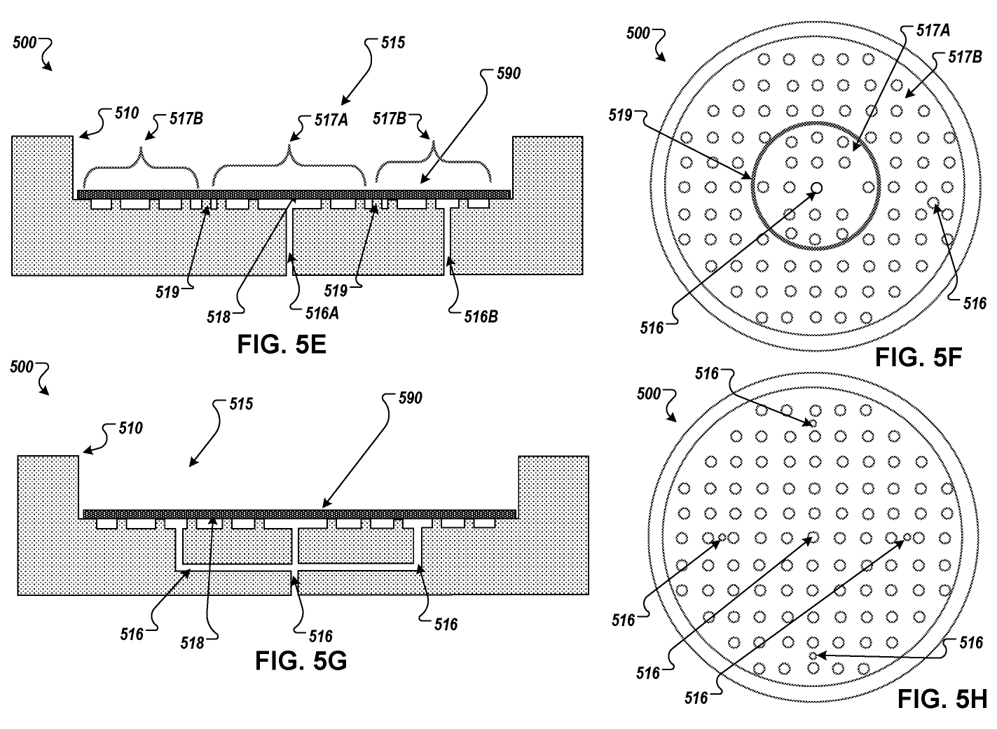

FIGS. 5A-H illustrates components of substrate support assemblies 500 (e.g., substrate support assemblies 400 of one or more of FIGS. 4A-B, substrate support assemblies 300 of one or more of FIGS. 3A-E, substrate support assemblies 200 of one or more of FIGS. 2A-D, and/or substrate support assembly 100 of FIG. 1), according to certain embodiments.

The substrate support assembly 500 may form one or more pockets 515 (e.g., recesses), where each pocket 515 is configured to receive a substrate. An upper surface of the ESC 510 (e.g., within each pocket 515) may have one or more protrusions 518 (e.g., mesas) to support the substrate. The gas channel 516 may be between protrusions 518. One or more protrusions 518 (e.g., concentric protrusions to which gas channels 516 provide gas) and/or gas channels 516 may cause different zones for cooling and/or vacuum chucking different portions of the substrate different than each other. In some embodiments, the gas channel 516 may be routed within the bulk (e.g., the block, the body, the ESC 510) of the substrate support assembly 500.

In some embodiments, the ESC 110 forms gas channels 116, where each of the gas channels 116 is associated with a cooling zone and/or vacuum chucking zone below the substrate.

In some embodiments, the ESC 110 forms one or more ledges at a perimeter portion of the substrate to reduce flow of the gas from below the substrate.

Referring to FIG. 5A, the ESC 510 may form a gas channel 516 to an underside of a substrate 590 and the ESC 510 may form one or more ledges (e.g., an annular ledge) to reduce (e.g., prevent) gas flow from under the substrate 590 (e.g., to above the substrate, to the inner volume of the chamber, etc.).

Referring to FIG. 5B, the gas channels 516 may be disposed at an edge of the substrate 590 to prevent deposition on the bottom of the substrate 590 (e.g., provide edge purge).

Referring to FIG. 5C, the gas channels 516 may be at the edges of the substrate 590 and under the substrate 590 (e.g., a mixture of FIGS. 5A-B).

Referring to FIG. 5D, the ESC 510 may include two pockets 515. The gas may be flown underside of the substrate 590 (e.g., wafer). This is the region where multiple zones may be located.

FIGS. 5E-H illustrate ESCs 110 that include one or more zones. In some embodiments, FIG. 5E-5F illustrate two zones and FIGS. 5G-H illustrate one zone. FIGS. 5E and 5G may be cross-sectional views and FIGS. 5F and 5H may be an upper view.

Referring to FIGS. 5E-F, ESC 110 may include zone 517A on an inner portion of the upper surface and an outer zone 517B on an outer portion of the upper surface. Gas channel 516A may provide gas to zone 517A and gas channel 516B may provide gas to zone 517B. One or more dividing features 519 (e.g., an annular protrusion that is configured to contact a lower surface of the substrate 590) may separate the different zones 517. Gas flow to the different zones 517 via the different gas channels 516 may be controlled to provide different flow rates to the different zones 517.

FIGS. 5G-H illustrate a single zone that is provided gas by a single gas channel 516 that is divided into different gas channels (e.g., gas routing) internal to the ESC 110 (e.g., ceramic body).

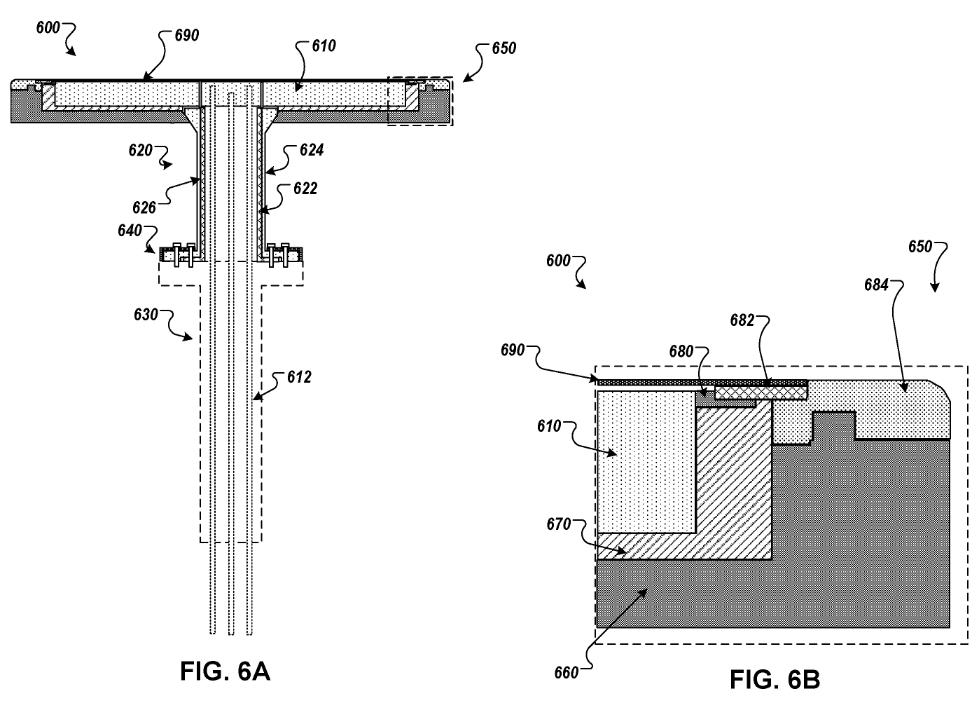

FIGS. 6A-B illustrate components of substrate support assemblies 600 (e.g., substrate support assemblies 500 of one or more of FIGS. 5A-C, substrate support assemblies 400 of one or more of FIGS. 4A-B, substrate support assemblies 300 of one or more of FIGS. 3A-E, substrate support assemblies 200 of one or more of FIGS. 2A-D, and/or substrate support assembly 100 of FIG. 1), according to certain embodiments. FIG. 6A may illustrate a cross-sectional view of a substrate support assembly 600 and FIG. 6B may illustrate an enlarged view of components of the substrate support assembly 600.

The substrate support assembly 600 may include a process kit ring assembly 650. The process kit ring assembly 650 may include one or more components (e.g., rings) include one or more of: component pipe 660 (e.g., quartz pipe); sliding ring 670; support ring 680 (e.g., silicon carbide (SiC) support ring); insert ring 682 (e.g., SiC insert ring); and/or component ring 684 (e.g., quartz ring).

In some embodiments, the process kit ring assembly 650 (e.g., edge ring) includes a sliding ring 670 that includes a first sliding ring portion disposed under the ESC 610 and a second sliding ring portion disposed to a side of the ESC 610 (e.g., heater).

In some embodiments, the process kit ring assembly 650 further includes a component pipe 660 (e.g., quartz pipe) that includes a first quartz pipe portion disposed under the first sliding ring portion and a second quartz pipe portion, where the second sliding ring portion is disposed between the ESC 110 (e.g., heater) and the second quartz pipe portion.

In some embodiments, the process kit ring assembly 650 further includes: a component ring 684 (e.g., quartz ring) disposed on the second quartz pipe portion; a support ring 680 disposed on the second sliding ring portion; and an insert ring 682 disposed at least partially on the support ring 680, the sliding ring 670, and the component ring 684 (e.g., quartz ring).

The process kit ring assembly 650 may include one or more components (e.g., component ring 684, inset ring 682, support ring 680, etc.) that are disposed to the sides of the substrate 690.

The process kit ring assembly 650 may provide edge tuning of the substrate 690 to provide a more uniform deposition at the edges of the substrate 690. The process kit ring assembly 650 (e.g., edge ring kit) may provide support for the substrate 690 during the deposition process. The components (e.g., rings) of the process kit ring assembly 650 may improve the tilt uniformity of the substrate processing system.

Use of process kit ring assembly 650 may allow threshold thermal conductance (e.g., proper thermal conductance) between the components (e.g., components of the process kit ring assembly 650, the substrate, the ESC 610). The process kit ring assembly 650 (e.g., edge process kit) may allow quick replacement of at least a portion of the process kit ring assembly 650 during chamber cleaning.

In some embodiments, the process kit ring assembly 650 forms one or more gas channels to provide gas to the underside of the substrate 690.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

Reference throughout this specification to “one embodiment,” “an embodiment,” or “some embodiments,” means that a particular feature, structure, or characteristic described in connection with the embodiment is included in at least one embodiment. Thus, the appearances of the phrase “in one embodiment,” “in an embodiment,” or “in some embodiments” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ± 1%, ± 2%, ± 5%, ± 10%, ± 15%, ± 20%, or ± 25%.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A substrate support assembly comprising:
an electrostatic chuck configured to support a substrate;
one or more heater shafts disposed below the electrostatic chuck, wherein the one or more heater shafts form one or more gas pathways and are configured to provide gas through the electrostatic chuck;
a heater shaft assembly disposed below the one or more heater shafts; and
a heater ring clamp configured to secure at least one of the one or more heater shafts to the heater shaft assembly.

2. The substrate support assembly of claim 1, wherein:
the one or more heater shafts comprise an inner heater shaft and an outer heater shaft disposed around the inner heater shaft;
the one or more gas pathways are between the inner heater shaft and the outer heater shaft; and
the inner heater shaft and the outer heater shaft are brazed or diffusion bonded together.

3. The substrate support assembly of claim 1, wherein the one or more heater shafts comprise a single heater shaft, wherein the one or more gas pathways are one or more through holes that pass through the single heater shaft.

4. The substrate support assembly of claim 1 further comprising one or more sealing components disposed between the one or more heater shafts and the heater shaft assembly.

5. The substrate support assembly of claim 1 further comprising:
a gas channel cover forming a gas channel cover channel;
a gas introducer forming a gas introducer channel, wherein the gas is to be provided through the gas introducer channel and the gas channel cover channel to the one or more gas pathways; and
one or more sealing components disposed between the gas channel cover and gas introducer.

6. The substrate support assembly of claim 5 further comprising a porous plug at least partially disposed in at least one of the gas introducer channel, the gas channel cover channel, or the electrostatic chuck.

7. The substrate support assembly of claim 1, wherein:
the gas comprises one or more of nitrogen, argon, or helium; and
one or more electrical conduits pass through a central portion of the one or more heater shafts to the electrostatic chuck.

8. The substrate support assembly of claim 1, wherein the gas is to provide cooling of the substrate that is processed with processing temperatures of at least 100 degrees Celsius.

9. The substrate support assembly of claim 1, wherein the electrostatic chuck forms a plurality of gas pathways, wherein each of the plurality of gas pathways is associated with a at least one of cooling zone or a vacuum clamping zone below the substrate.

10. The substrate support assembly of claim 1, wherein the electrostatic chuck forms one or more ledges at a perimeter portion of the substrate to reduce flow of the gas from below the substrate.

11. The substrate support assembly of claim 1 further comprising a process kit ring assembly comprising a sliding ring comprising a first sliding ring portion disposed under the electrostatic chuck and a second sliding ring portion disposed to a side of the electrostatic chuck.

12. The substrate support assembly of claim 11, wherein the process kit ring assembly further comprises a quartz pipe comprising a first quartz pipe portion disposed under the first sliding ring portion and a second quartz pipe portion, wherein the second sliding ring portion is disposed between the electrostatic chuck and the second quartz pipe portion.

13. The substrate support assembly of claim 12, wherein the process kit ring assembly further comprises:
a quartz ring disposed on the second quartz pipe portion;
a support ring disposed on the second sliding ring portion; and
an insert ring disposed at least partially on the support ring, the sliding ring, and the quartz ring.

14. The substrate support assembly of claim 1, wherein the gas is to flow from the one or more heater shafts to the substrate to provide cooling to manage thermal uniformity of the substrate in a deposition environment.

15. The substrate support assembly of claim 1, wherein the substrate support assembly is disposed in a chamber formed by a processing chamber, wherein the gas is to flow from the chamber to the one or more heater shafts to provide vacuum clamping on the substrate to enable thermal tuning of the substrate in a deposition environment.

16. A substrate support assembly comprising:
an electrostatic chuck configured to support a substrate;
an inner heater shaft disposed below the electrostatic chuck;
an outer heater shaft disposed around the inner heater shaft below the electrostatic chuck, wherein one or more gas pathways are formed between the inner heater shaft and the outer heater shaft that provide gas through the electrostatic chuck to at least one of provide cooling to manage thermal uniformity of the substrate in a deposition environment or provide vacuum clamping on the substrate to enable thermal tuning of the substrate in the deposition environment; and
a heater shaft assembly disposed below the inner heater shaft and the outer heater shaft.

17. The substrate support assembly of claim 16, wherein the inner heater shaft and the outer heater shaft are brazed or diffusion bonded together.

18. The substrate support assembly of claim 16 further comprising at least one of:
a heater ring clamp configured to secure at least one of the inner heater shaft or the outer heater shaft to the heater shaft assembly; or
a process kit ring assembly comprising:
a sliding ring comprising a first sliding ring portion disposed under the electrostatic chuck and a second sliding ring portion disposed to a side of the electrostatic chuck;
a quartz pipe comprising a first quartz pipe portion disposed under the first sliding ring portion and a second quartz pipe portion, wherein the second sliding ring portion is disposed between the electrostatic chuck and the second quartz pipe portion.

19. A substrate support assembly comprising:
an electrostatic chuck configured to support a substrate;
a heater shaft disposed below the electrostatic chuck, wherein the heater shaft forms one or more though holes that are configured to provide gas through the electrostatic chuck to at least one of provide cooling to manage thermal uniformity of the substrate in a deposition environment or provide vacuum clamping on the substrate to enable thermal tuning of the substrate in the deposition environment; and
a heater shaft assembly disposed below the heater shaft.

20. The substrate support assembly of claim 19 further comprising at least one of:
a heater ring clamp configured to secure the heater shaft to the heater shaft assembly; or
a process kit ring assembly comprising:
a sliding ring comprising a first sliding ring portion disposed under the electrostatic chuck and a second sliding ring portion disposed to a side of the electrostatic chuck;
a quartz pipe comprising a first quartz pipe portion disposed under the first sliding ring portion and a second quartz pipe portion, wherein the second sliding ring portion is disposed between the electrostatic chuck and the second quartz pipe portion.
